(19) United States
(12) Patent Application Publication
(10) Pub. No.: US 2015/0214268 A1
(43) Pub. Date: Jul. 30, 2015

(54) IMAGE SENSOR AND METHOD FOR FABRICATING THE SAME

(71) Applicant: SK hynix Inc., Gyeonggi-do (KR)

(72) Inventor: Sang-Sik KIM, Gyeonggi-do (KR)

(21) Appl. No.: 14/308,483

(22) Filed: Jun. 18, 2014

(30) Foreign Application Priority Data
Jan. 28, 2014 (KR) 10-2014-0010522

(51) Int. Cl. H01L 27/146

(52) U.S. Cl. CPC H01L 27/14645; H01L 27/14621; H01L 27/14627; H01L 27/14685; H01L 27/14636; H01L 27/1463

(57) ABSTRACT

An image sensor includes a substrate including two or more photoelectric conversion regions corresponding to two or more pixels respectively, two or more color filters formed on the substrate corresponding to the photoelectric conversion regions, an interlayer insulation layer including an interconnection line and formed on the substrate, two or more condensing patterns each having a plurality of high refractive index regions and a plurality of low refractive index i regions, which are alternately disposed, wherein line widths of the high and low refractive index regions are different in the respective condensing patterns depending on the pixels.

### CROSS-REFERENCE TO RELATED APPLICATIONS

The present application claims priority of Korean Patent Application No. 10-2014-0010522, filed on Jan. 28, 2014, which is incorporated herein by reference in its entirety.

### BACKGROUND

1. Field

Exemplary embodiments of the present invention relate to a semiconductor design technology, and more particularly, to an image sensor including a digital microlens and a method for fabricating the same.

2. Description of the Related Art

An image sensor is a semiconductor device, which changes an optical image into an electrical signal. The image sensor includes a plurality of pixels, which are arranged in a two-dimensional matrix. Each of the pixels includes a photoelectric conversion region, generates a photo-charge on the photoelectric conversion region in response to incident light, and outputs a pixel signal corresponding to the incident light using a generated photo-charge.

Since the condensing lens of a conventional image sensor is curved, there is limited optical refraction efficiency. It has difficulty in application where there is a large chief ray angle (CRA). To ameliorate this concern, a digital microlens (DML) has been developed. The digital microlens concentrates light using a high refractive index layer and a low refractive index layer, and may be formed in a concavoconvex shape using a double pattern. However, the concavo-convex shape of the digital microlens may cause defective pixels due to the fabrication process.

### SUMMARY

Exemplary embodiments of the present invention are directed to an image sensor capable of preventing a defect in a digital microlens and a method for fabricating the same.

In accordance with an exemplary embodiment of the present invention, an image sensor includes a substrate including two or more photoelectric conversion regions corresponding to two or more pixels, respectively, two or more color filters formed on the substrate corresponding to the photoelectric conversion regions, respectively, an interlayer insulation layer including an interconnection line and formed on the substrate, two or more condensing patterns each having a plurality of high refractive index regions and a plurality of low refractive index regions, which are alternately disposed, wherein line widths of the high and low refractive index regions are different in the respective condensing patterns depending on the pixels

The condensing pattern may include a refractive index distribution type of optical film.

The condensing patterns may each have one of the plurality of high refractive index regions on a center thereof, which has a wider line width in a first condensing pattern than others, among the condensing patterns, wherein the first condensing pattern corresponds to a first pixel illuminated by a longer wavelength of incident light than others, among the pixels.

In each of the condensing patterns, the high refractive index regions may have a smaller line width as the high refractive index regions are disposed farther away from a center of the condensing pattern, which receives incident light.

The color filters may include a red filter, a green filter and a blue filter, and the condensing patterns may include first to third condensing patterns corresponding to the color filters, wherein the condensing patterns each have one of the plurality of high refractive index regions on a center thereof, which has a largest line width in the first condensing pattern and a smallest line width in the third condensing pattern.

The high refractive index regions and the low refractive index regions may be alternately disposed in a parallel direction to the substrate.

The condensing pattern may include a microlens.

The image sensor may further include a planarization layer formed between the color filter and the microlens.

In accordance with an exemplary embodiment of the present invention, a method for fabricating an image sensor includes forming two or more color filters corresponding to two or more photoelectric conversion regions on a substrate including the photoelectric conversion regions, and forming two or more condensing patterns on the color filters by alternately disposing high refractive index regions and low refractive index regions, wherein line widths of the high and low refractive index regions are different in the respective condensing patterns depending on pixels.

The forming of the condensing patterns may include forming a refractive index distribution type of optical film on the color filters, forming a mask pattern on the refractive index distribution type of optical film, and patterning the high refractive index regions and the low refractive index regions by illuminating light to the refractive index distribution type of optical film using the mask pattern as a barrier.

The method may further include baking the refractive index distribution type of optical film, after the patterning of the high refractive index region and the low refractive index region.

The method may further include forming a planarization layer on the color filters before the forming of the condensing patterns.

The color filters may include a red filter, a green filter and a blue filter, and the condensing patterns may include first to third condensing patterns corresponding to the color filters, wherein the condensing patterns each have one of the plurality of high refractive index regions on a center thereof, which has a largest line width in the first condensing pattern and a smallest line width in the third condensing pattern.

In accordance with an exemplary embodiment of the present invention, an image sensor includes a substrate including a photoelectric conversion region, a color filter formed on the substrate corresponding to the photoelectric conversion region, an interlayer insulation layer including an interconnection line and formed on the substrate, and a condensing pattern including a plurality of high refractive index regions and a plurality of low refractive index regions, which are alternately disposed, wherein the high refractive index regions have a smaller line width as the high refractive index regions are disposed farther away from a center of the condensing pattern, while the low refractive index regions have a larger line width as the low refractive index regions are disposed farther away from the center of the condensing pattern.

### BRIEF DESCRIPTION OF THE DRAWINGS

FIG. 1 is an equivalent circuit diagram illustrating an image sensor in accordance with an exemplary embodiment of the present invention.

FIG. 2 is a plane diagram illustrating a pixel of an image sensor in accordance with an exemplary embodiment of the present invention.

FIG. 3 is a cross sectional view illustrating an image sensor in accordance with an exemplary embodiment of the present invention.

FIG. 4 is a cross sectional view illustrating a microlens in accordance with an exemplary embodiment of the present invention.

FIGS. 5A to 5C are cross sectional views illustrating a method for fabricating an image sensor in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals correspond directly to the like parts in the various figures and embodiments of the present invention.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

It is also noted that in this specification, ‘and/or’ represents that one or more of components arranged before and after ‘and/or’ is included. Furthermore, “connected/coupled” refers to one component not only directly coupling another component but also indirectly coupling another component through an intermediate component. In addition, a singular form may include a plural form, and vice versa, as long as it is not specifically mentioned in a sentence. Furthermore, ‘include/comprise’ or ‘including/comprising’ used in the specification represents that one or more components, steps, operations, and elements exist or are added.

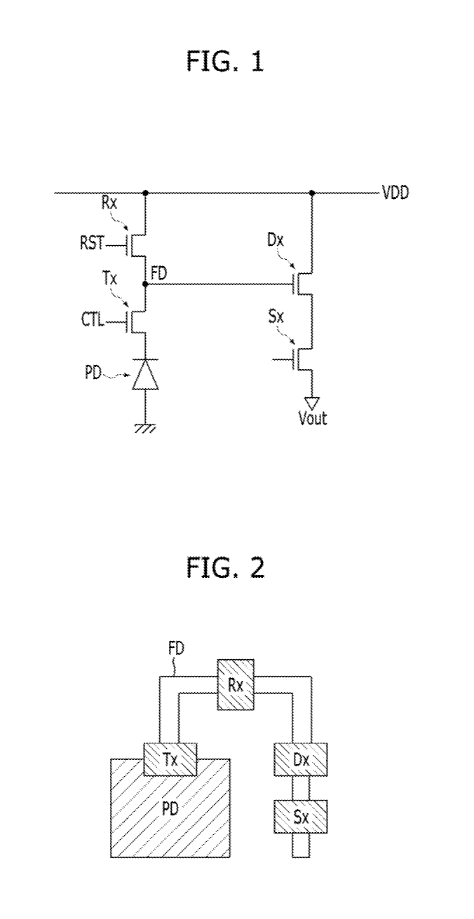

FIG. 1 is an equivalent circuit diagram illustrating an image sensor in accordance with an exemplary embodiment of the present invention. FIG. 2 is a plane diagram illustrating a pixel of an image sensor in accordance with an exemplary embodiment of the present invention.

As shown in FIGS. 1 and 2, a pixel of an image sensor includes a photo diode PD, a transfer transistor Tx, a floating diffusion region FD, a reset transistor Rx, a drive transistor Dx and a selection transistor Sx.

The photo diode PD may be included in a photoelectric conversion region, which receives light, and generates and accumulates a photo-charge.

The transfer transistor Tx transfers the photo-charge accumulated by the photo diode PD to the floating diffusion region FD in response to a transfer control signal CTL inputted through a gate thereof.

The floating diffusion region FD receives and stores the photo-charge transferred through the transfer transistor Tx.

The reset transistor Rx is coupled between a power supply voltage VDD terminal and the floating diffusion region FD. The reset transistor Rx resets the floating diffusion region FD by draining the photo-charge stored in the floating diffusion region FD with the power supply voltage VDD in response to a reset signal RST. The floating diffusion region FD may be electrically coupled to a drive gate of the drive transistor Dx.

The drive transistor Dx performs a function of a source follower-typed buffer amplifier and buffers a signal in response to the photo-charge stored in the floating diffusion region FD. The drive transistor Dx and the reset transistor Rx may be coupled in series.

The selection transistor Sx performs switching and an addressing operations.

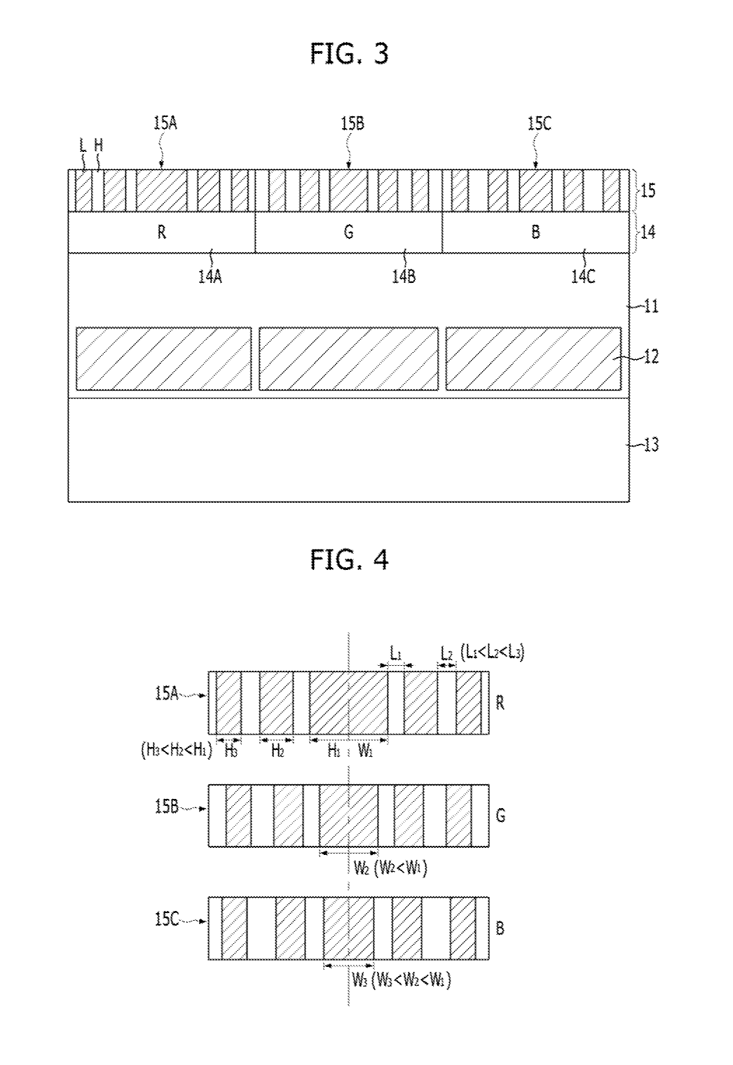

FIG. 3 is a cross sectional view illustrating an image sensor in accordance with an exemplary embodiment of the present invention.

Referring to FIG. 3, an element isolation layer (not shown) for isolating neighboring pixels from a photoelectric conversion region 12 is formed in a substrate 11 having a plurality of pixels. An interlayer insulation layer 13 having a signal generating circuit (not shown) is formed on a front side of the substrate 11. A color filter 14 and a condensing pattern 15 are formed on a back side of the substrate 11.

The substrate 11 may include a semiconductor substrate. The semiconductor substrate may include a single crystal type of silicon containing material. For example, the substrate 11 may include a bulk silicon substrate or a silicon-on insulator (SOI) substrate.

The photoelectric conversion region 12 may include a plurality of photoelectric conversion units (not shown), which are vertically overlapped. Each of the plurality of photoelectric conversion units may include a photo diode having an N-type impurity region and a P-type impurity region. The photoelectric conversion region 12 may penetrate the substrate 11 to be formed in both a front side and a back side of the substrate 11 (i.e., at the same level). In another embodiment, the photoelectric conversion region 12 may be formed in a front side of the substrate 11 and apart from a back side of the substrate 11 (i.e., at different levels).

The interlayer insulation layer 13 may include at least one material selected from a group of an oxide, a nitride and an oxynitride. The signal generation circuit (not shown) formed in the interlayer insulation layer 13 may include a plurality of transistors (not shown), a multi-layer metal interconnection line (not shown) and a contact plug (not shown), which couples them therebetween. The signal generation circuit (not shown) generates a pixel signal corresponding to a photo-charge generated in the photoelectric conversion region 12.

The color filter 14 may be formed corresponding to the photoelectric conversion region 12. For example, a red filter 14A, a green filter 14B and a blue filter 14C may be formed corresponding to the photoelectric conversion region 12 of a red pixel R, a green pixel G and a blue pixel B, respectively. If an image sensor includes an infrared photoelectric conversion region 12 (or other type of electromagnetic wave conversion region), an infrared filter (or other type of electromagnetic wave filter) corresponding to an infrared receiving element may be formed.

The condensing pattern 15 performs a function of a microlens and may include a digital microlens without an embossed surface. Especially, the condensing pattern 15 may include a refractive index distribution type of optical film having a high refractive index region H and a low refractive index region L, which are alternately disposed.

The refractive distribution type of optical film contains materials having different refractive indexes between a portion where light illuminates and the other portion where light does not illuminate. The high refractive index region and the low refractive index region of the refractive distribution type of optical film may be patterned through an exposure. The portion where the light illuminates may be the high refractive index region of the optical film, or the portion where the light does not illuminate may be the high refractive index region of optical film depending on the characteristics of the optical film.

Line widths of the high refractive index region H and the low refractive index region L of the condensing pattern 15 may be different depending on the pixel. For example, line widths of the high refractive index region H and the low refractive index region L of the condensing pattern 15A corresponding to the red pixel R may be different from line widths of the high refractive index region H and the low refractive index region L of the microlens corresponding to the green pixel G or the blue pixel B. Details will be described with reference to FIG. 4.

As described above, the condensing pattern 15 in accordance with an embodiment of the present invention may include a refractive index distribution type of optical film and form a digital microlens without an embossed surface (i.e., with a planar surface). The condensing pattern 15 may adjust a refractive index depending on the wavelength of incident light by differently forming the line widths of the high refractive index region H and the low refractive index region L depending on the pixel.

In an embodiment of the present invention, the condensing pattern 15 is formed on the color filter 14. However, in another embodiment of the present invention, a planarization layer (not shown) may be further formed between the color filter 14 and the condensing pattern 15.

In another embodiment of the present invention, by forming an embossed layer and a condensing pattern 15 having the refractive index distribution type of optical film on a color filter 14, refractive index efficiency may be increased through a combination of the embossed and the high and low refractive index regions.

In another embodiment: of the present invention, by forming a color filter having a different thickness depending on a pixel, and then forming a condensing pattern including a refractive index distribution type of optical film on the color filter, the refractive index efficiency may be increased through a combination of an embossed surface of the color filter and high and low refractive index regions.

FIG. 4 is a cross sectional view illustrating a microlens in accordance with an exemplary embodiment of the present invention.

Referring to FIG. 4, a condensing pattern corresponding to one of the pixels, e.g., a red pixel R, a green pixel G and a blue pixel B may include a refractive index distribution type of optical film having a high refractive index region H and a low refractive index region L, which are alternately disposed. The high refractive index region H and the low refractive index region L of the condensing pattern may be different depending on the corresponding pixel.

The red pixel R having the longest wavelength of visible incident light may have a wider line width W₁ than a line width of different pixels based on the center of the condensing pattern. More specifically, the line width W₁ of a central high refractive index region of the red pixel R is wider than the line width W₂ of a central high refractive index region of the green pixel G. The line width W₂ of the central high refractive index region of the green pixel G is wider than the line width W₃ of a central high refractive index region of the blue pixel B. That is, depending on the wavelength of incident light, the line width of the central high refractive index region of the red pixel R, the green pixel G and the blue pixel B may be expressed as below, W₁>W₂>W₃. In the exemplary embodiments of the present invention, although only the red pixel, the green pixel and the blue pixel are shown in drawings, other color pixels may be used, and the line widths of the central high refractive index regions may be different from each other depending on the wavelength of incident light.

The high refractive index region of each condensing pattern has a smaller line width as it is disposed farther away from the center of the condensing pattern. That is, the line width of the high refractive index region of the red pixel R, the green pixel G and the blue pixel B may be expressed as below, H₁>H₂>H₃.

Moreover, the line width of the high refractive index region is not limited as shown in the drawings. In another embodiment of the present invention, the line width of the high refractive index region may be sequentially increased or be the same.

The line width of a low refractive index corresponding to the red pixel R, the green pixel G and the blue pixel B is may be increased as the low refractive index is farther away from a center of the condensing pattern. That is, the line width of the high refractive index region of the red pixel R, the green pixel G and the blue pixel B may be expressed as below, L₁<L₂<L₃.

Moreover, the line width of the low refractive index region is not limited as shown in the drawings. In another embodiment of the present invention, the line width of the low refractive index region may be sequentially reduced or be the same.

In the exemplary embodiments of the present invention, the light is substantially concentrated on the center of the condensing pattern. In another embodiment of the present invention, the receiving position of light may be shifted in to the left side or the right side.

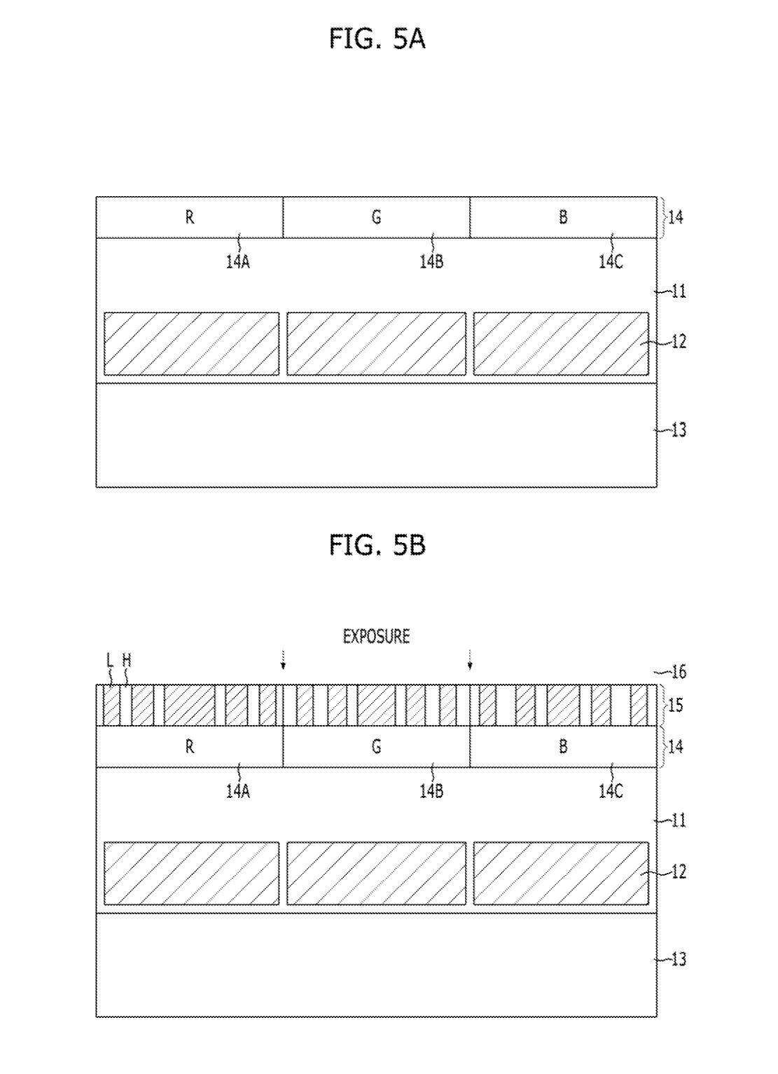

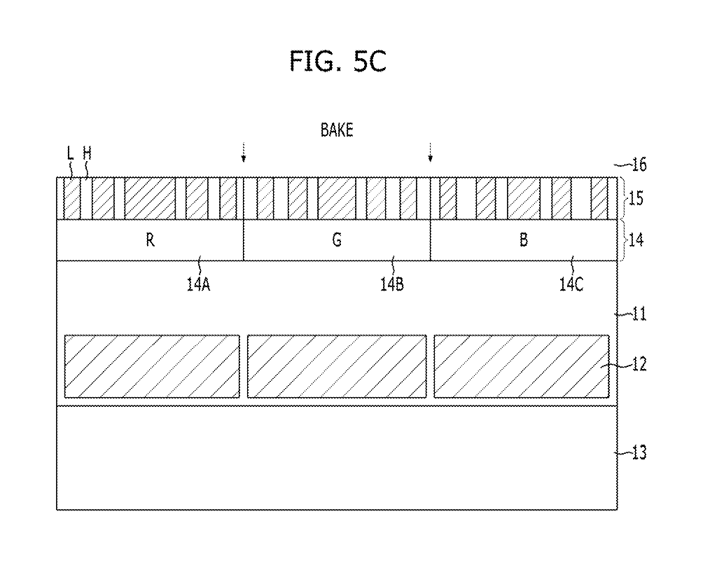

FIGS. 5A to 5C are cross sectional views illustrating a method for fabricating an image sensor in accordance with an exemplary embodiment of the present invention.

Referring to FIG. 5A, a substrate 11 wherein a plurality of pixels are defined, is prepared. The substrate 11 may include a semiconductor substrate. The semiconductor substrate may include a single crystal type of silicon containing material. For example, the substrate 11 may include a bulk silicon substrate or a silicon-on insulator (SOI) substrate.

Subsequently, the element isolation region (not shown) may be formed on the substrate 11 along a border region between the plurality of pixels. The element isolation region may be formed by forming an element isolation trench, a d performing a shallow trench isolation (STI) process for gap-filling an insulation material in the element isolation trench.

Next, the photoelectric conversion region 12 may be formed in the substrate 11. The photoelectric conversion region 12 may include a plurality of photoelectric conversion units (not shown), which are vertically overlapped. Each of the plurality of photoelectric conversion units may include a photo-diode having an N-type impurity region and a P-type impurity region. The photo-diode may be formed through an impurity ion implant process.

Subsequently, the interlayer insulation layer 13 including the signal generation circuit may be formed on the front side of the substrate 11. The interlayer insulation layer 13 may include at least one material selected from a group of an oxide, a nitride and an oxynitride, and may have a multi-layer structure. The signal generation circuit (not shown) formed in the interlayer insulation layer 13 may include a plurality of transistors (not shown), a multi-layer metal interconnection line (not shown) and a contact plug (not shown), which couples them therebetween. The signal generation circuit (not shown) generates a pixel signal corresponding to a photo-charge generated in the photoelectric conversion region 12. The plurality of transistors may include the transfer transistor Tx, the selection transistor Sx, the reset transistor Rx and an access transistor Ax.

Next, a thinning process may be performed on a back side of the substrate 11. The thinning process increases light receiving efficiency by reducing the thickness of the substrate 11 and decreasing the approach distance of incident light to the photoelectric conversion region 12. The thinning process may be performed through a back-grinding process and a polishing process.

Subsequently, the color filter 14 may be formed on the back side of the substrate 11. The color filter 14 may be formed at a disposition corresponding to the photoelectric conversion region 12. For example, the red filter 14A, the green filter 14B and the blue filter 14C may be formed at the disposition corresponding to the photoelectric conversion region 12 of the red pixel R, the green pixel G and the blue pixel B. In another embodiment of the present invention, if the image sensor includes a photoelectric conversion region 12 of an infrared pixel, an infrared filter may be formed.

Referring to FIG. 5B, the condensing pattern 15 may be formed on the color filter 14. Before the condensing pattern 15 is formed, a planarization layer (not shown) may be further formed.

The condensing pattern 15 may include a plurality of microlenses such that the incident light from the back side of the substrate 11 focuses on the photoelectric conversion region 12 of a corresponding pixel. The incident light, which is received through the condensing pattern 15, is selected by the color filter, e.g., a red filter R, a green filter G and a blue filter B, or an infrared filter. The selected light may be received by the photoelectric conversion region 12 of the corresponding pixel.

The condensing pattern 15 may include a digital microlens without an embossed surface. Especially, the condensing pattern 15 may include a refractive index distribution type of optical film. The refractive index distribution type of optical film may be a material having different refractive indexes on a light illumination region and a non-illumination region.

Next, the high refractive index region H and the low refractive index region L may be patterned by performing an exposure process on the condensing pattern 15 including the refractive index distribution type of optical film. The high refractive index region H and the low refractive index region L may be patterned to be alternately disposed along the surface of the substrate 11.

The line widths of the high refractive index region H and the low refractive index region L of the condensing pattern 15 may be different depending on the pixel. For example, the lines widths of the high refractive index region H and the low refractive index region L of the condensing pattern 15A corresponding to the red pixel R may be different from the line widths of the high refractive index region H and the low refractive index region L of the condensing patterns 15B and 15C corresponding to the green pixel G and the blue pixel B. The lines widths of the high refractive index region H and the low refractive index region L of the condensing pattern 15 may be defined as shown in FIG. 2.

Referring to FIG. 5C, a bake process may be performed on the condensing pattern 15 to have more robust physical characteristics. That is, the condensing pattern 15 may become more solid through the bake process. The bake process may be performed through a thermal treatment process. For example, the bake process may be performed through the thermal treatment process at a temperature of 200° C. for 5 to 15 minutes. In another embodiment of the present invention, the thermal treatment process and a processing time may be changed under conditions where the physical characteristics of the condensing pattern 15 are not changed.

Hereinafter, the image sensor may be fabricated through a known fabrication method.

While the present invention has been described with respect to the specific embodiments, it will be apparent to those skilled in the art that various changes and modifications may be made without departing from the spirit and scope of the invention as defined in the following claims.

What is claimed is:

1. An image sensor, comprising.
a substrate including two or more photoelectric conversion regions corresponding to two or more pixels, respectively;
two or more color filters formed on the substrate corresponding to the photoelectric conversion regions, respectively;
an interlayer insulation layer including an interconnection line and formed on the substrate; and
two or more condensing patterns each having a plurality of high refractive index regions and a plurality of low refractive index regions, which are alternately disposed,
wherein line widths of the high and low refractive index regions are different in the respective condensing patterns depending on the pixels.

2. The image sensor of claim 1, wherein the condensing pattern includes a refractive index distribution type of optical film.

3. The image sensor of claim 1, wherein the condensing patterns each have one of the plurality of high refractive index regions on a center thereof, which has a wider line width in a first condensing pattern than others, among the condensing patterns,
wherein the first condensing pattern corresponds to a first pixel illuminated by a longer wavelength of an incident light than others, among the pixels.

4. The image sensor of claim 1, wherein, in each of the condensing patterns, the high refractive index regions have a smaller line width as the high refractive index regions are disposed farther away from a center of the condensing pattern, which receives an incident light.

5. The image sensor of claim 1, wherein the color filters include a red filter, a green filter and a blue filter, and the condensing patterns include first to third condensing patterns corresponding to the color filters,
wherein the condensing patterns each have one of the plurality of high refractive index regions on a center thereof, which has a largest line width in the first condensing pattern and a smallest line width in the third condensing pattern.

6. The image sensor of claim 1, wherein the high refractive index regions and the low refractive index regions are alternately disposed in a parallel direction to the substrate.

7. The image sensor of claim wherein the condensing pattern include a microlens.

8. The image sensor of claim 7, further comprising:
a planarization layer formed between the color filter and the microlens.

9. A method for fabricating an image sensor, comprising:
forming two or more color filters corresponding to two or more photoelectric conversion regions on a substrate including the photoelectric conversion regions; and
forming two or more condensing patterns on the color filters by alternately disposing high refractive index regions and low refractive index regions,
wherein line widths of the high and low refractive index regions are different in the respective condensing patterns depending on pixels.

10. The method of claim 9, wherein the forming of the condensing patterns includes:
forming a refractive index distribution type of optical film on the color filters;
forming a mask pattern on the refractive index distribution type of optical film; and
patterning the high refractive index regions and the low refractive index regions by illuminating a light to the refractive index distribution type of optical film using the mask pattern as a barrier.

11. The method of claim 10, further comprising:
baking the refractive index distribution type of optical film, after the patterning of the high refractive index region and the low refractive index region.

12. The method of claim 9, further comprising:
forming a planarization layer on the color filters before the forming of the condensing patterns.

13. The method of claim 9, wherein the color filters include a red filter, a green filter and a blue filter, and the condensing patterns include first: to third condensing patterns corresponding to the color filters,
wherein the condensing patterns each have one of the plurality of high refractive index regions on a center thereof, which has a largest line width in the first condensing pattern and a smallest line width in the third condensing pattern.

14. An image sensor, comprising:
a substrate including a photoelectric conversion region;
a color filter formed on the substrate corresponding to the photoelectric conversion region;
an interlayer insulation layer including an interconnection line and formed on the substrate; and
a condensing pattern including a plurality of high refractive index regions and a plurality of low refractive index regions, which are alternately disposed,
wherein the high refractive index regions have a smaller line width as the high refractive index regions are disposed farther away from a center of the condensing pattern, while the low refractive index regions have a larger line width as the low refractive index regions are disposed farther away from the center of the condensing pattern.
